(19) United States
(12) Patent Application Publication
(10) Pub. No.: US 2004/0203257 A1
(43) Pub. Date: Oct. 14, 2004

(54) Processing method of semiconductor substrate

(75) Inventors: Takeshi Yoshida, Tokyo (JP); Tohru Koyama, Tokyo (JP); Yoji Mashiko, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/697,277

(22) Filed: Oct. 31, 2003

(30) Foreign Application Priority Data
Apr. 9, 2003 (JP) 2003-105272

(51) Int. Cl. H01L 21/26; H01L 21/00; G02B 3/00; H01L 31/0232; C03C 15/00

(52) U.S. Cl. 438/798; 359/642; 359/648; 438/795; 438/27; 257/432; 216/26; 216/65

(57) ABSTRACT

A processing technique of a semiconductor substrate which can improve a capability of a solid immersion lens in case of processing the semiconductor substrate and forming the solid immersion lens on its surface is provided.

A focused ion beam (5) is irradiated on a semiconductor substrate (1), and a salient part (2) acting as a solid immersion lens is formed on its main surface (3a). At this time, a cutting amount of the semiconductor substrate (1) by the focused ion beam (5) is adjusted by making the irradiation time of the focused ion beam (5) to the semiconductor substrate (1) change. According to this, a surface of the salient part (2) has a curved surface of high precision, and a capability of the salient part (2) as the solid immersion lens is improved.

### BACKGROUND OF THE INVENTION

1. Field of the Invention

The present invention relates to a technique to form a solid immersion lens on a surface of a semiconductor substrate.

2. Description of the Background Art

According to a tendency of semiconductor devices such as LSI and so on having a multilayer wiring, it becomes difficult to evaluate and analyze a semiconductor substrate from a top surface, and an approach from a back surface of the semiconductor substrate is necessary. As for a major failure analysis method from the back surface, an emission analysis performing the failure analysis by detecting a weak light generated in a point where a current leaks, an OBIC (Optical Beam Induced Current) and an OBRCH (Optical Beam Induced Resistance CHange) identifying a fault point by converting a change of an electromotive current or a power source current generated by an irradiation of a laser beam into an image, moreover, a laser voltage probe (LVP) to monitor a wave form of a potential in an arbitrary point by catching a strength or a phase change of a reflected light of an irradiated laser beam and so on. With regard to these analyses from the back surface of the semiconductor substrate (described simply as a “back surface analysis” hereinafter), it is necessary to have access to a semiconductor element formed on a top surface of a semiconductor substrate through the semiconductor substrate in a thickness of a few hundred μm, thus an infrared transmitting silicon is generally employed. However, a wave length of the infrared which is to be employed is 1 μm or more, and a spatial resolution is effectively 0.7 μm or more, thus an image resolution has to be sacrificed by an application of the back surface analysis.

Consequently, a technique employing a solid immersion lens composed of silicon is suggested in “High spatial resolution subsurface microscopy”, Applied Physics Letters, Vol. 78, No. 26, June 2001, pp. 4071-4073 by S. B. Ippolito et al. as a technique to improve the spatial resolution. This technique is to obtain a resolution transcending a limit of the analysis restricted by a wave length of a light by increasing a refractive index of a medium of the light.

According to the technique described in the document by S. B. Ippolito et al., a focusing angle can be made to increase significantly as compared with a case that there is no solid immersion lens by making a hemispherical solid immersion lens cohere on a back surface of the semiconductor substrate and putting the light transmitting silicon in the semiconductor substrate through that solid immersion lens. A resolution d is expressed as d=λ/(2·n·sin θ), and a numeral aperture NA expressed as n·sin θ can be improved ideally to a multiplication of a square of the refractive index n by an application of the solid immersion lens. Besides, θ and λ described above express a half angle of the focusing angle and the wave length of the light, respectively.

However, with regard to the technique described in the document by S. B. Ippolito et al., there is a case that the resolution deteriorate to a large degree, when a gap occurs between the semiconductor substrate and the solid immersion lens. Consequently, a technique to form the solid immersion lens and the semiconductor substrate in one by processing the semiconductor substrate, forming a hemispherical salient part on its surface and employing this salient part as a solid immersion lens is described in Japanese Patent Application Laid-Open No. 2002-189000.

With regard to the technique described in Japanese Patent Application Laid-Open No. 2002-189000, the salient part acting as the solid immersion lens and the semiconductor substrate are formed in one, thus the gap does not occur between the solid immersion lens and the semiconductor substrate, and the resolution improves more as compared with the technique described in the document by S. B. Ippolito et al.

Besides, a related art of the technique described in Japanese Patent Application Laid-Open No. 2002-189000 is described in a prior application applied by the present applicant (unpublished), and an application number of the prior application is “Japanese Patent Application No. 2003-5550”.

With regard to the technique described in Japanese Patent Application Laid-Open No. 2002-189000, when the salient part acting as the solid immersion lens is formed on the surface of the semiconductor substrate, the semiconductor substrate is processed with employing a polishing tool whose section has a semicircular trench. Accordingly, it is difficult to finish a surface of the salient part to be a curved surface of high precision. As a result, a lens capability of the salient part as the solid immersion lens cannot be brought out sufficiently.

### SUMMARY OF THE INVENTION

It is an object of the present invention to provide a processing technology of a semiconductor substrate which can improve a capability of a solid immersion lens in case of processing the semiconductor substrate and forming the solid immersion lens on a surface of the semiconductor substrate.

A first processing method of a semiconductor substrate according to the present invention includes steps (a) and (b). The step (a) is a step of preparing a semiconductor substrate. The step (b) is a step of processing the semiconductor substrate with irradiating a focused ion beam on a main surface of the semiconductor substrate and forming a salient part which acts as a solid immersion lens and has a curved surface on its main surface. In the step (b), a cutting amount of the semiconductor substrate is adjusted by making an irradiation time of the focused ion beam to the semiconductor substrate change corresponding to an irradiation position of the focused ion beam to the semiconductor substrate.

The cutting amount of the semiconductor substrate is adjusted by the irradiation time of the focused ion beam, thus the surface of the salient part can be finished to be the curved surface of high precision. Accordingly, a capability of the salient part as the solid immersion lens is improved.

A second processing method of a semiconductor substrate according to the present invention includes steps (a) and (b). The step (a) is a step of preparing a semiconductor substrate. The step (b) is a step of processing the semiconductor substrate with irradiating a laser in an etching gas atmosphere and forming a salient part which acts as a solid immersion lens and has a curved surface on its main surface. In the step (b), a cutting amount of the semiconductor substrate is adjusted by making an irradiation time of the laser to the semiconductor substrate change corresponding to an irradiation position of the laser to the semiconductor substrate.

The cutting amount of the semiconductor substrate is adjusted by the irradiation time of the laser, thus the surface of the salient part can be finished to be the curved surface of high precision. Accordingly, a capability of the salient part as the solid immersion lens is improved.

A third processing method of a semiconductor substrate according to the present invention includes steps (a) and (b). The step (a) is a step of preparing a semiconductor substrate. The step (b) is a step of processing the semiconductor substrate and forming a salient part which acts as a solid immersion lens and has a curved surface on its main surface. The step (b) includes steps (b-1) and (b-2). The step (b-1) is a step of placing a mask which is composed of a material of which a cutting amount per unit of time by a focused ion beam is substantially identical with that of the semiconductor substrate and has a shape similar to that of the salient part on the main surface of the semiconductor substrate. The step (b-2) is a step of irradiating a focused ion beam on the mask and the semiconductor substrate until the mask is removed from an upper side of the mask and forming the salient part on the main surface.

The focused ion beam is irradiated on the semiconductor substrate and the mask until the mask having a shape similar to that of the salient part is removed, and the salient part is formed, thus the salient part which has a curved surface of high precision can be formed on the main surface of the semiconductor substrate. Accordingly, a capability of the salient part as the solid immersion lens is improved.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A, 1B are drawings illustrating a structure of a semiconductor substrate manufactured by a processing method of a semiconductor substrate according to a preferred embodiment 1 of the present invention.

FIG. 2 is a perspective view illustrating the structure of the semiconductor substrate manufactured by the processing method of the semiconductor substrate according to the preferred embodiment 1 of the present invention.

FIG. 3 is a cross-sectional view illustrating the processing method of the semiconductor substrate according to the preferred embodiment 1 of the present invention.

FIGS. 4A, 4B are drawings illustrating the structure of the semiconductor substrate manufactured by the processing method of the semiconductor substrate according to the preferred embodiment 1 of the present invention.

FIGS. 5A, 5B are cross-sectional views illustrating a processing method of a semiconductor substrate according to a preferred embodiment 2 of the present invention.

FIGS. 6A, 6B are cross-sectional views illustrating a processing method of a semiconductor substrate according to a preferred embodiment 3 of the present invention.

FIGS. 7A, 7B and 8A, 8B are cross-sectional views both illustrating a processing method of a semiconductor substrate according to a preferred embodiment 4 of the present invention.

FIGS. 9A, 9B to 11A, 11B are cross-sectional views all illustrating a processing method of a semiconductor substrate according to a preferred embodiment 5 of the present invention.

### DESCRIPTION OF THE PREFERRED EMBODIMENTS

### Preferred Embodiment 1

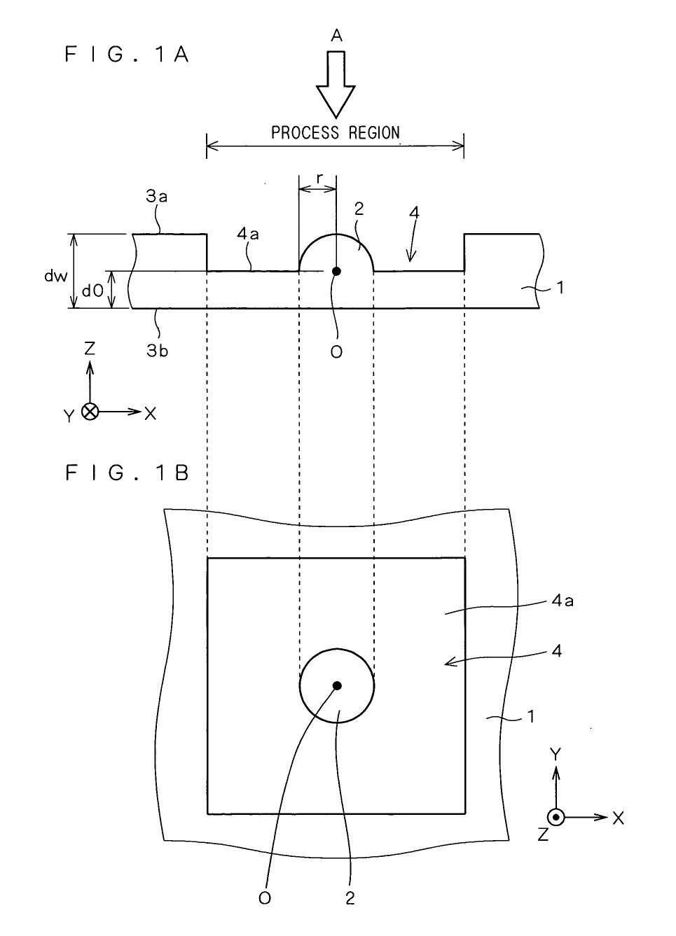

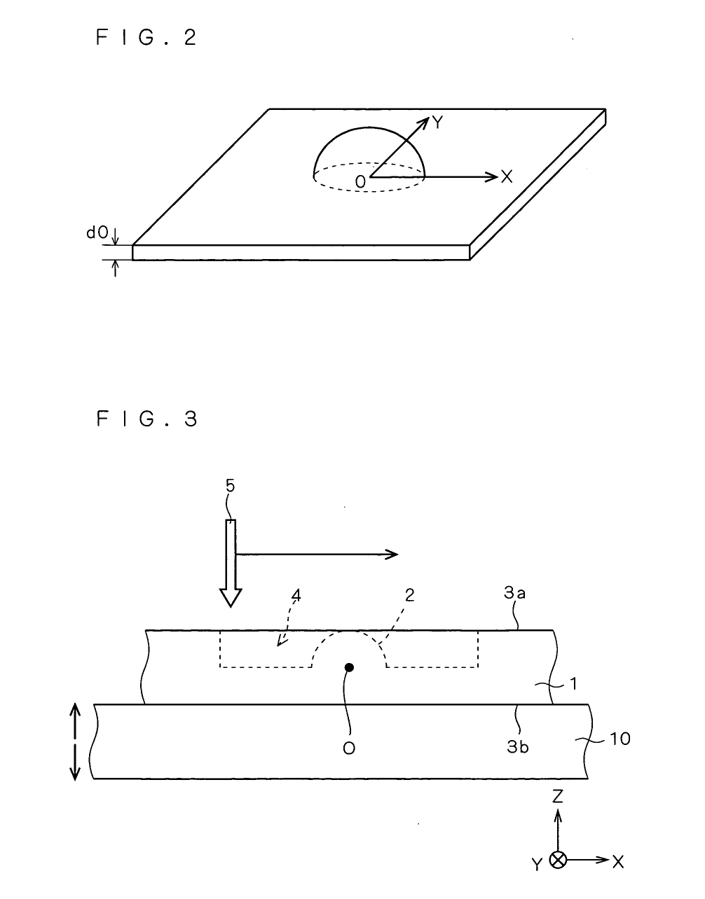

First, a semiconductor substrate 1 manufactured by a processing method of a semiconductor substrate according to the preferred embodiment 1 of the present invention is described. FIGS. 1A, 1B are drawings illustrating a structure of that semiconductor substrate 1, and FIG. 1A illustrates its cross-sectional view, and moreover, FIG. 1B illustrates a plane view in case of viewing from an arrow view A. Moreover, FIG. 2 is a perspective view that only a process region of the semiconductor substrate 1 shown in FIG. 1A is taken out and illustrated.

As shown in FIGS. 1A, 1B and 2, a concave part 4 is formed on one main surface 3a of the semiconductor substrate 1, for example, which is a silicon substrate, and a salient part 2 is formed on a bottom surface 4a of that concave part 4. As described hereinafter, the concave part 4 and the salient part 2 are formed with processing the semiconductor substrate 1 from its main surface 3a, thus they are united with each other.

The salient part 2 is a hemisphere, for example, and its surface constitutes a hemispherical surface. Moreover, a sphere diameter r of the salient part 2 is 300 μm, for example, and its center O is placed in a position of a distance d0 in a thickness direction from other main surface 3b of the semiconductor substrate 1 toward its inside. Besides, a thickness dw of the semiconductor substrate 1 is 400 μm, for example, and the distance d0 is 100 μm, for example. Moreover, a distance between the bottom surface 4a of the concave part 4 and the other main surface 3b of the semiconductor substrate 1 in a thickness direction of the semiconductor substrate 1 is also the same as the distance d0.

The salient part 2 constituting such a shape as described above acts as a spherical lens, and is employed as a solid immersion lens in case of performing a back surface analysis to a semiconductor element formed on the other main surface 3b of the semiconductor substrate 1 (not illustrated) and so on. For example, with regard to an emission analysis, a light generated from a point where a current leaks in the semiconductor element is taken out to an outside of the semiconductor substrate 1 through the salient part 2. Moreover, a failure analysis and so on are performed with employing the light taken out in this manner. Moreover, with regard to an OBIC, a laser beam is irradiated on the semiconductor element through the salient part 2, and the failure analysis and so on are performed with employing a change of an electromotive current generated by that irradiation.

Next, the processing method of the semiconductor substrate according to the present preferred embodiment 1 which enables a formation of the semiconductor substrate 1 shown in FIGS. 1A, 1B and 2 is described. In the present preferred embodiment 1, as shown in FIGS. 1A, 1B and 2, a three dimensional rectangular coordinate system Q1 that the center O of the salient part 2 is supposed to be an origin and the thickness direction of the semiconductor substrate 1 is supposed to be a Z axis is defined, and the processing method of the semiconductor substrate according to the present preferred embodiment 1 is described hereinafter with employing this rectangular coordinate system Q1.

FIG. 3 is a cross-sectional view illustrating a processing method according to the present preferred embodiment 1. As shown in FIG. 3, in the processing method of the present preferred embodiment 1, the semiconductor substrate 1 is processed with irradiating a focused ion beam 5 on the main surface 3a of the semiconductor substrate 1 with employing an existing focused ion beam device, and the salient part 2 acting as the solid immersion lens is formed on the main surface 3a of the semiconductor substrate 1, and moreover, the concave part 4 is formed on the main surface 3a of the semiconductor substrate 1. Moreover, a cutting amount of the semiconductor substrate 1 by the focused ion beam 5 is adjusted by an irradiation time of the focused ion beam 5 to the semiconductor substrate 1. A concrete description follows hereinafter.

In the rectangular coordinate system Q1 defined as described above, the focused ion beam 5 is moved to its irradiation position with moving along an X axis and a Y axis, and after stopping it in that position, an irradiation time t is made to change corresponding to the irradiation position of the focused ion beam. The irradiation time t at this time is expressed as a mathematical expression (1) hereinafter.

If x²<r² and y²<r²,

t=1/a0×(dw−d0−(r²−x²−y²)^{1/2})

If x²≧r² or y²≧r²,

t=1/a0×(dw−d0) (1)

In this regard, a coefficient a0 indicates a cutting amount of the semiconductor substrate 1 in a Z axis direction per unit of time when the focused ion beam 5 is irradiated just in focus on an unit area of the main surface 3a of the semiconductor substrate 1, and in case that a focused ion beam current is set up to be 10 μA, for example, it is supposed to be 0.1 μm per second. Moreover, parameters x and y indicate a value of an X-coordinate and a value of a Y-coordinate of the irradiation position of the focused ion beam 5, respectively. Hereinafter, there is a case that the parameters x and y are indicated as a two-dimensional position (x, y) of the focused ion beam 5 and the parameter x is indicated as one-dimensional position x of the focused ion beam 5, respectively.

As indicated in the mathematical expression (1) described above, the irradiation time t when the salient part 2 is formed, that is to say, the irradiation time t in case of x²<r² and y²<r² changes depending on a value of the two-dimensional position (x, y) of the focused ion beam 5, and the irradiation time t when a part where the salient part 2 is not formed in the concave part 4 is formed, that is to say, the irradiation time t in case of x² ≧r² or y²≧r² is constant.

Additionally, when irradiating the focused ion beam 5 on the semiconductor substrate 1 and processing it, as shown in FIG. 3, the semiconductor substrate 1 is placed on a stage 10 which can move up and down along the Z axis direction. Moreover, the semiconductor substrate 1 is made to move in a positive direction of the Z axis with a proceeding of a substrate processing in a negative direction of the Z axis so that the focused ion beam 5 is constantly irradiated just in focus on the main surface 3a of the semiconductor substrate 1 during the substrate processing, too.

In case of processing a certain point in the main surface 3a of the semiconductor substrate 1, a processed surface changes the position from its original position, the main surface 3a of the semiconductor substrate 1, to a deeper position as the substrate processing proceeds. Accordingly, it is necessary to make the semiconductor substrate 1 move in the positive direction of the Z axis according to the proceeding of the substrate processing to make a focus of the focused ion beam 5 accord with the processed surface during the substrate processing, too.

For example, when a total cutting amount in a certain point of the main surface 3a of the semiconductor substrate 1 in the Z axis direction is indicated as G, the substrate processing proceeds at a constant speed in the negative direction of the Z axis, thus the stage 10 is made to move at a rate of G/t (t indicates the irradiation time) in the positive direction of the Z axis. Moreover, after a processing in that point is finished, that is to say, t seconds later, the stage 10 is returned to a primary position. Moreover, the irradiation position of the focused ion beam 5 is made to move, and a processing in a next point is performed in the same manner. By repeating this action, the focus of the focused ion beam 5 is supposed to accord with the processed surface constantly, and the cutting amount of the semiconductor substrate 1 can be adjusted only by the irradiation time t of the focused ion beam 5.

In this manner, according to the processing method of the semiconductor substrate according to the present preferred embodiment 1, the cutting amount of the semiconductor substrate 1 is adjusted by making the irradiation time t of the focused ion beam 5 change corresponding to the irradiation position of it, thus the surface of the salient part 2 can be finished to be a curved surface of higher precision as compared with that of a processing method described in Japanese Patent Application Laid-Open No. 2002-189000. Accordingly, a capability of the salient part 2 as the solid immersion lens can be improved, and precision of the back surface analysis is improved.

Besides, it is also possible to form the salient part 2 acting as a non-spherical lens on the main surface 3a of the semiconductor substrate 1 in addition to the salient part 2 acting as the spherical lens by employing the processing method of the semiconductor substrate according to the present preferred embodiment 1. A concrete description on the processing method of the substrate in this case follows hereinafter.

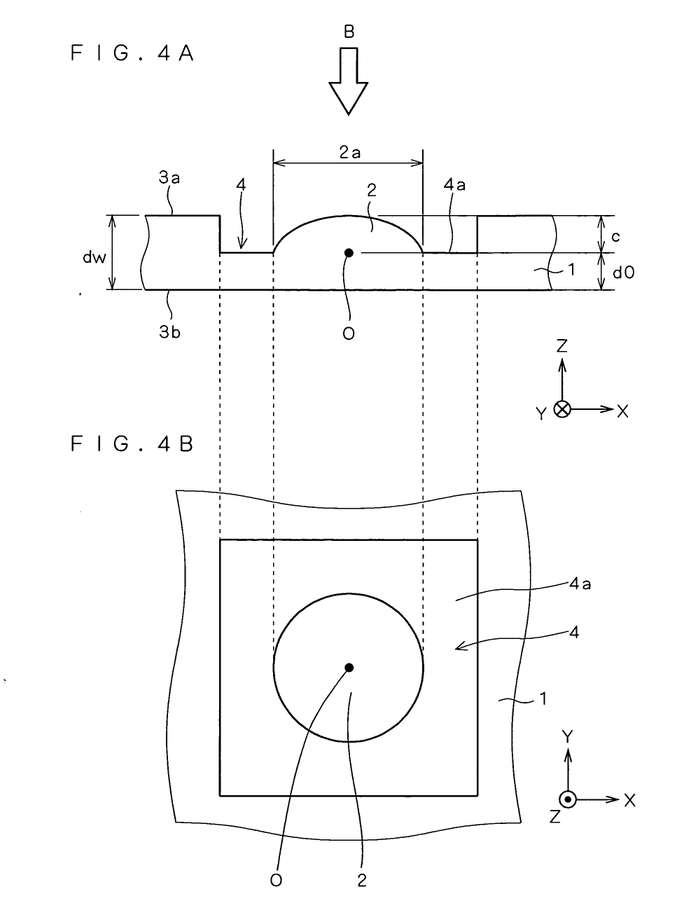

FIGS. 4A, 4B are cross-sectional views illustrating a structure of the semiconductor substrate 1 including the salient part 2 acting as the non-spherical lens on the main surface 3a in exchange for the salient part 2 acting as the spherical lens in the semiconductor substrate 1 shown in FIGS. 1A, 1B. FIG. 4A illustrates a cross-sectional view of that semiconductor substrate 1, and FIG. 4B illustrates a plane view in case of viewing from an arrow view B.

As shown in FIGS. 4A, 4B, the salient part 2 is, for example, a semiellipsoid, and its surface is formed of a semielliptical surface. This semielliptical surface is, for example, a part of a spheroid of long sideways which is obtained with rotating an ellipse having a minor axis in a thickness direction of the semiconductor substrate 1 and a long axis in a direction at right angles with the minor axis around the minor axis. According to this, a cross-sectional shape of the salient part 2 shown in FIG. 4A is a part of an ellipse, and a plane shape of the salient part 2 shown in FIG. 4B has a circular form.

The center O of the salient part 2 which is the semiellipoid is placed in the position of the distance d0 in the thickness direction from the other main surface 3b of the semiconductor substrate 1 toward its inside. Moreover, as shown in FIGS. 4A, 4B, a three dimensional rectangular coordinate system Q2 that this center O is supposed to be an origin and the thickness direction of the semiconductor substrate 1 is supposed to be the Z axis is defined.

The surface of the salient part 2 is formed of the semielliptical surface, thus when employing this rectangular coordinate system Q2, the shape of the surface of the salient part 2 can be expressed as a mathematical expression (2) hereinafter.

$$\frac{{X}^{2}}{{a}^{2}} + \frac{{Y}^{2}}{{b}^{2}} + \frac{{Z}^{2}}{{c}^{2}} = 1 ( Z \geq 0 ) \qquad ( 2 )$$

In this regard, coefficients a, b and c in the mathematical expression (2) described above indicate half lengths of three main axes of the semielliptical surface of the salient part 2, and are, for example, set up to be 400 μm, 400 μm and 300 μm, respectively.

Besides, the thickness dw of the semiconductor substrate 1 shown in FIGS. 4A, 4B is 400 μm, for example, and the distance d0 is 100 μm, for example. Moreover, the distance between the bottom surface 4a of the concave part 4 in the thickness direction of the semiconductor substrate 1 and the other main surface 3b of the semiconductor substrate 1 is also the same as the distance d0.

The salient part 2 having such a shape as described above acts as the non-spherical lens, and is employed as the solid immersion lens in case of performing the back surface analysis.

In case of forming the salient part 2 shown in FIGS. 4A, 4B by the processing method according to the present preferred embodiment 1, an irradiation time t of the focused ion beam 5 is set up as described hereinafter.

If x²<a² and y²<b²,

t=1/a0×(dw−d0−c×(1−x²/a²−y²/b²)^{1/2})

If x²≧a² or y²≧b²,

t=1/a0×(dw−d0) (3)

Moreover, in the same manner as a case of forming the salient part 2 of the spherical lens, when processing the semiconductor substrate 1, the semiconductor substrate 1 is placed on a stage 10, and the semiconductor substrate 1 is made to move in the positive direction of the Z axis with a proceeding of a substrate processing in the negative direction of the Z axis so that the focused ion beam 5 is constantly irradiated just in focus on the main surface 3a of the semiconductor substrate 1 during the substrate processing, too. According to this, the cutting amount of the semiconductor substrate 1 can be adjusted only by the irradiation time t of the focused ion beam 5. Accordingly, the surface of the salient part 2 acting as the non-spherical lens can be finished to be the curved surface of high precision, and a capability of the salient part 2 as the solid immersion lens can be improved.

### Preferred Embodiment 2

In the preferred embodiment 1 described above, the cutting amount of the semiconductor substrate 1 is adjusted by making the irradiation time t of the focused ion beam 5 change, however, in the present preferred embodiment 2, the irradiation time t is constant, and a processing method to adjust the cutting amount of the semiconductor substrate 1 by making a focal position Fz of the focused ion beam 5 change is suggested.

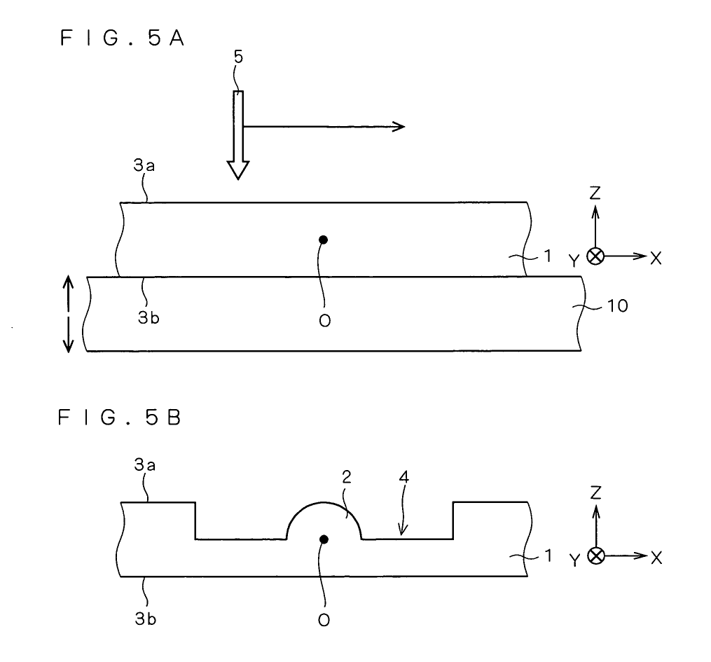

FIGS. 5A, 5B are cross-sectional views illustrating a processing method of the semiconductor substrate according to the present preferred embodiment 2. A structure shown in FIG. 5A is a cross-sectional structure of the semiconductor substrate 1 before the process, and a structure shown in FIG. 5B is a cross-sectional structure of the semiconductor substrate 1 after the process. Besides, the semiconductor substrate 1 shown in FIG. 5B is the same as the semiconductor substrate 1 shown in FIG. 1A.

In the processing method of the present preferred embodiment 2, the focused ion beam 5 is moved to its irradiation position with making it move along the X axis and the Y axis in the rectangular coordinate system Q1, and after stopping it in that position, the focal position Fz is made to change corresponding to the two-dimensional position (x, y) of the focused ion beam 5. A concrete description follows hereinafter.

First, as shown in FIG. 5A, the semiconductor substrate 1 before the process is placed on the stage 10 which can move in the Z axis direction. Moreover, with employing an existing focused ion beam device, the semiconductor substrate 1 is processed with making the irradiation position of the focused ion beam 5 to the main surface 3a of the semiconductor substrate 1 move along the X axis direction and the Y axis direction, and the salient part 2 acting as the solid immersion lens is formed on its main surface 3a. At this time, the irradiation time t of the focused ion beam 5 is constant, and its focal position Fz is made to change corresponding to the value of the two-dimensional position (x, y) of the focused ion beam 5.

For example, in case of setting up the value of the irradiation time t of the focused ion beam 5 in the two-dimensional position (x, y) the same as that of the unit of time employed when the coefficient a0 in the mathematical expression (1) described above is defined, the focal position Fz in case of setting the focal position just in focus to be “1” can be expressed as a mathematical expression (4) hereinafter.

If x²<r² and y²<r²,

Fz=((dw−d0−(r²−x²−y²)^{1/2})/a0)^{1/2}

If x²≧r² or y²≧r²,

Fz=((dw−d0)/a0)^{1/2} (4)

As indicated in the mathematical expression (4) described above, the focal position Fz when forming the salient part 2, that is to say, the focal position Fz in case of x²<r² and y²<r² changes depending on a value of the two-dimensional position (x, y) of the focused ion beam 5, and the focal position Fz when forming a part where the salient part 2 is not formed in the concave part 4, that is to say, the focal position Fz in case of x²≧r² or y²≧r² is constant.

Besides, a square of the focal position of the focus ion beam has a proportional relation with its energy density, and the energy density has a proportional relation with the cutting amount of the semiconductor substrate. Accordingly, as also recognized from the mathematical expression (4) described above, the square of the focal position of the focused ion beam has a proportional relation with the cutting amount of the semiconductor substrate.

As described above, in case of processing a certain point in the main surface 3a of the semiconductor substrate 1, a processed surface changes the position from its original position, the main surface 3a of the semiconductor substrate 1, to a deeper position as the substrate processing proceeds. Accordingly, it is necessary to make the semiconductor substrate 1 move in the positive direction of the Z axis with the proceeding of the substrate processing to maintain the focal position Fz of the focused ion beam 5 to be the value expressed as the mathematical expression (4) during the substrate processing, too.

Consequently, in the same manner as the preferred embodiment 1, the semiconductor substrate 1 is made to move in the positive direction of the Z axis by making the stage 10 move in the positive direction of the Z axis with the proceeding of the substrate processing in the negative direction of the Z axis.

For example, when a total cutting amount in a certain point of the main surface 3a of the semiconductor substrate 1 in the Z axis direction is indicated as G, the substrate processing proceeds at a constant speed in the negative direction of the Z axis, thus the stage 10 is made to move at a rate of G/t (t indicates the irradiation time) in the positive direction of the Z axis. Moreover, after a processing in that point is finished, the stage 10 is returned to a primary position. Moreover, the irradiation position of the focused ion beam 5 is made to move, the focal position Fz corresponding to the irradiation position after moving is set up, and a processing in a next point is performed in the same manner. By repeating this action, the focal position Fz of the focused ion beam 5 is supposed to have constantly the value expressed as the mathematical expression (4) even during the substrate processing, and the cutting amount of the semiconductor substrate 1 can be adjusted only by the focal position Fz of the focused ion beam 5.

In this manner, with regard to the processing method of the semiconductor substrate according to the present preferred embodiment 2, the cutting amount of the semiconductor substrate 1 is adjusted by making the focal position Fz of the focused ion beam 5 change corresponding to the irradiation position of it, thus the surface of the salient part 2 can be finished to be a curved surface of higher precision as compared with a processing method described in Japanese Patent Application Laid-Open No. 14-189000 (2002) by a different method with that of the preferred embodiment 1 described above. Accordingly, a capability of the salient part 2 as the solid immersion lens can be improved, and precision of the back surface analysis is improved.

Besides, it is also possible to form the salient part 2 acting as a non-spherical lens as shown in FIGS. 4A, 4B described above on the main surface 3a of the semiconductor substrate 1 by employing the processing method of the semiconductor substrate according to the present preferred embodiment 2. In this case, the focal position Fz is set up as described hereinafter.

If x²<a² and y²<b²,

Fz=((dw−d0−c×(1−x²/a²−y²/b²)¹²)/a0)^{1/2}

If x²≧a² or y²≧b²,

Fz=((dw−d0)/a0) (5)

In this regard, the focal position Fz in the mathematical expression (5) described above is the focal position when setting the focal position just in focus to be “1” in case of setting up the value of the irradiation time t of the focused ion beam 5 in the two-dimensional position (x, y) the same as that of the unit of time employed when the coefficient a0 in the mathematical expression (1) described above is defined.

Moreover, also in case of forming the salient part 2 of the non-spherical lens, the semiconductor substrate 1 is made to move in the positive direction of the Z axis with the proceeding of the substrate processing in the negative direction of the Z axis to maintain constantly the value of the focused ion beam 5 to be expressed as the mathematical expression (5) described above during the substrate processing, too.

In this manner, the salient part 2 acting as the non-spherical lens can be formed on the main surface 3a of the semiconductor substrate 1 by adjusting the focal position Fz of the focused ion beam 5, thus a capability of that salient part 2 as the solid immersion lens can be improved.

### Preferred Embodiment 3

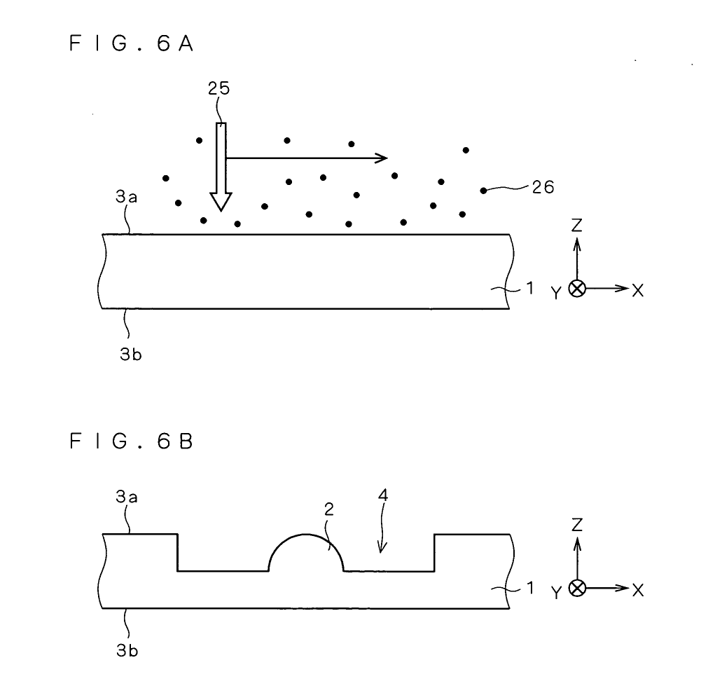

FIGS. 6A, 6B are cross-sectional views illustrating a processing method of the semiconductor substrate according to the preferred embodiment 3 of the present invention. A structure shown in FIG. 6A is a cross-sectional structure of the semiconductor substrate 1 before the process, and a structure shown in FIG. 6B is a cross-sectional structure of the semiconductor substrate 1 after the process. Besides, the semiconductor substrate 1 shown in FIG. 6B is the same as the semiconductor substrate 1 shown in FIG. 1A.

In the preferred embodiment 1 described above, the cutting amount of the semiconductor substrate 1 is adjusted by making the irradiation time t of the focused ion beam 5 change, however in the present preferred embodiment 3, the cutting amount of the semiconductor substrate 1 is adjusted by making an irradiation time t of a laser 25 change in an etching gas 26 atmosphere as shown in FIGS. 6A, 6B.

For example, the salient part 2 acting as the solid immersion lens is formed on the main surface 3a of the semiconductor substrate 1 by irradiating a helium neon laser on the main surface 3a of the semiconductor substrate 1 and processing the semiconductor substrate 1 in a XeF₂ (xenon difluoride) gas atmosphere acting as the etching gas 26. At this time, the helium neon laser is made to move to its irradiation position with moving along the X axis and the Y axis in the rectangular coordinate system Q1, and after stopping it in that position, the irradiation time t of the helium neon laser is made to change corresponding to its irradiation position. According to this, in the same manner as the preferred embodiment 1, the surface of the salient part 2 can be finished to be the curved surface of high precision. Accordingly, the capability of the salient part 2 as the solid immersion lens can be improved, and precision of the back surface analysis is improved.

Besides, the irradiation time t in the present preferred embodiment 3 can be expressed as the mathematical expression (1) described above, in the same manner as the preferred embodiment 1. In this regard, the coefficient a0 indicates a cutting amount of the semiconductor substrate 1 in the Z axis direction per unit of time in case of irradiating the laser 25 on the main surface 3a of the semiconductor substrate 1 in the etching gas 26 atmosphere. Moreover, the laser 25 is employed in exchange for the focused ion beam 5 in the present preferred embodiment 3, thus as opposed to the preferred embodiment 1, it is not necessary to make the semiconductor substrate 1 move in the positive direction of the Z axis with the proceeding of the substrate processing.

Moreover, it is also possible to form the salient part 2 acting as the non-spherical lens on the semiconductor substrate 1 as shown in FIGS. 4A, 4B with setting up the irradiation time t of the laser 25 as the mathematical expression (3) described above and employing the processing method according to the present preferred embodiment 3.

### Preferred Embodiment 4

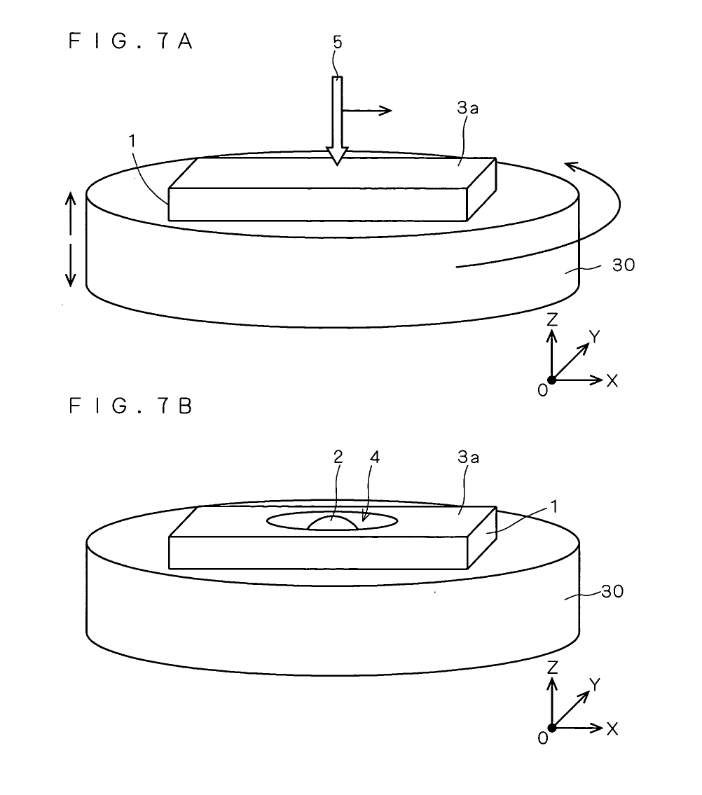

FIGS. 7A, 7B are cross-sectional views illustrating a processing method of the semiconductor substrate according to the preferred embodiment 4 of the present invention. A structure shown in FIG. 7A is a structure of the semiconductor substrate 1 before the process, and a structure shown in FIG. 7B is a structure of the semiconductor substrate 1 after the process. Besides, the semiconductor substrate 1 shown in FIG. 7B has the same shape as that of the semiconductor substrate 1 shown in FIG. 1A except for the shape of the concave part 4.

In the preferred embodiments 1 and 2 described above, the semiconductor substrate 1 is processed with making the irradiation position of the focused ion beam 5 move along the X axis and the Y axis in the rectangular coordinate system Q1, however, in the present preferred embodiment 4, the semiconductor substrate 1 is processed with making the semiconductor substrate 1 rotate at constant speed with the Z axis as an axis of rotation as shown in FIG. 7A. A concrete description follows hereinafter.

First, the semiconductor substrate 1 before the process is placed on a stage 30 which can rotate with the Z axis as the axis of rotation, and the stage 30 is made to rotate. According to this, the semiconductor substrate 1 rotates with the Z axis as the axis of rotation. The stage 30 is made to rotate at a rate of once every two seconds, for example.

Next, the semiconductor substrate 1 is processed with making the irradiation position of the focused ion beam 5 to the main surface 3a of the semiconductor substrate 1 move along the X axis direction with making the semiconductor substrate 1 rotate. At this time, the irradiation time t of the focused ion beam 5 is made to change corresponding to its value of one-dimensional position X. Concretely, the irradiation time t is set up as described hereinafter.

If x²<r²,

t=2πx/a0×(dw−d0−(r²−x²)^{1/2})

If x²≧r²,

t=2πx/a0×(dw−d0) (6)

Moreover, as described in the preferred embodiment 1, the processed surface changes the position from its original position, the main surface 3a of the semiconductor substrate 1, to the deeper position as the substrate processing proceeds, thus the semiconductor substrate 1 is made to move in the positive direction of the Z axis with the proceeding of the substrate processing to the negative direction of the Z axis so that the focused ion beam 5 is constantly irradiated just in focus on the main surface 3a of the semiconductor substrate 1 during the substrate processing, too. The stage 30 described above can move along the Z axis direction, and the semiconductor substrate 1 can be made to move along the Z axis by making that stage 30 move in the Z axis direction.

The surface of the salient part 2 shown in FIGS. 1A, 1B described above has the hemispherical shape, thus the surface of the salient part 2 can be said to have a curved surface of rotation with the Z axis in the rectangular coordinate system Q1 as the axis of rotation. That is to say, a part of a spherical surface obtained by making a circle formed on an XZ plain surface or a YZ plain surface rotate around the Z axis becomes the surface of the salient part 2 shown in FIGS. 1A, 1B. Accordingly, the salient part 2 can be formed by irradiating the focused ion beam 5 on the main surface 3a of the semiconductor substrate 1 with making the semiconductor substrate 1 rotate with the Z axis as the axis of rotation such as the processing method according to the present preferred embodiment 4. Besides, the process is performed with making the semiconductor substrate 1 rotate, thus the shape of concave part 4 formed with the salient part 2 is different from that of the concave part 4 shown in FIGS. 1A, 1B, and a plain shape viewed from the Z axis direction of the concave part 4 has a circular form.

In this manner, in the processing method of the semiconductor substrate according to the present preferred embodiment 4, the semiconductor substrate 1 is processed with being rotated, thus the surface of the salient part 2 can be finished to be the curved surface of higher precision. Accordingly, precision of the back surface analysis is furthermore improved.

Besides, even if the salient part 2 acts as the non-spherical lens and has the shape shown in FIGS. 4A, 4B as its surface, said salient part 2 can be formed by the processing method according to the present preferred embodiment 4.

As described in the preferred embodiment 1, the surface of the salient part 2 shown in FIGS. 4A, 4B can be said to have the curved surface of rotation with the Z axis in the rectangular coordinate system Q2 as the axis of rotation, by reason that it is the part of the spheroid of long sideways which is obtained with rotating the ellipse having the minor axis in the thickness direction of the semiconductor substrate 1 and the long axis in the direction at right angles with the minor axis around the minor axis. Accordingly, in the same manner as the salient part 2 having the hemispherical shape as its surface, the salient part 2 acting as the non-spherical lens can be formed on the main surface 3a of the semiconductor substrate 1 by making the irradiation position of the focused ion beam 5 move along the X axis direction with making the semiconductor substrate 1 rotate with the Z axis as the axis of rotation. Besides, the irradiation time t in this case can be expressed as a mathematical expression (7) hereinafter.

If x²<a²,

t=2πx/a0×(dw−d0−c×(1−x²/a²)^{1/2})

If x²≧a²,

t=2πx/a0×(dw−d0) (7)

Moreover, in the processing method of the present preferred embodiment 4, the salient part 2 acting as the solid immersion lens can be formed also by making the focal position Fz of the focused ion beam 5 change such as the case in the preferred embodiment 2 in exchange for making the irradiation time t of the focused ion beam 5 change. Concretely, the salient part 2 can be formed by making the focal position Fz of the focused ion beam 5 change corresponding to one-dimensional position x with making its irradiation position move along the X axis direction with making the semiconductor substrate 1 rotate at the constant speed with the Z axis as the axis of rotation.

In case of forming the salient part 2 shown in FIGS. 1A, 1B, the focal position Fz is set up as a mathematical expression (8) hereinafter, and in case of forming the salient part 2 shown in FIGS. 4A, 4B, the focal position Fz is set up as a mathematical 10 expression (9) hereinafter.

If x²<r²,

Fz=((dw−d0−(r²−x²)¹²)×2πx/a0)^{1/2}

If x²≧r²,

Fz=((dw−d0)×2πx/a0)^{1/2} (8)

If x²<a²,

Fz=((dw−d0−c×(1−x²/a²)^{1/2})×2πx/a0)^{1/2}

If x²≧a²,

Fz=((dw−d0)×2πx/a0)^{1/}² (9)

Besides, the focal position Fz in the mathematical expressions (8) and (9) is a focal position when the focal position just in focus is set to be “1” in case that the irradiation time t of the focused ion beam 5 in one-dimensional position x is set up to be the same value as that of the unit of time employed when defining the coefficient a0 in the mathematical expression (1) described above.

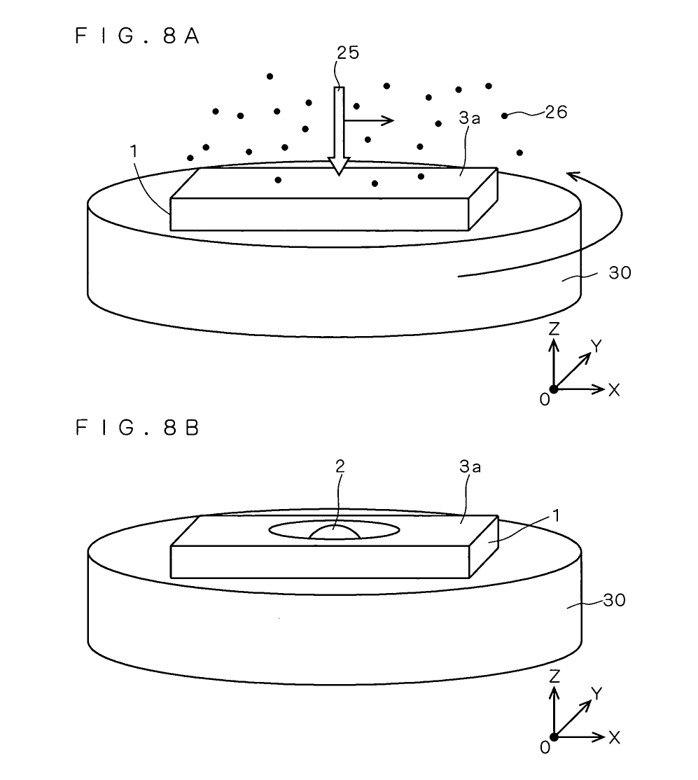

Moreover, even in case that the cutting amount of the semiconductor substrate 1 is adjusted by making the irradiation time t of the laser 25 change in the etching gas 26 atmosphere such as the preferred embodiment 3 described above, the salient part 2 acting as the solid immersion lens can be formed on the main surface 3a of the semiconductor substrate 1 by processing it with being rotated with the Z axis as the axis of rotation as shown in FIGS. 8A, 8B. The irradiation time t of the laser at this time is expressed as the mathematical expression (6) described above. Besides, a structure shown in FIG. 8A is a structure of the semiconductor substrate 1 before the process, and a structure shown in FIG. 8B is a structure of the semiconductor substrate 1 after the process. Besides, the semiconductor substrate 1 shown in FIG. 8B has the same shape as that of the semiconductor substrate 1 shown in FIG. 7B.

In this manner, the surface of the salient part 2 can be finished to be the curved surface of higher precision by processing the semiconductor substrate 1 by irradiating the laser 25 with making the semiconductor substrate 1 rotate in the etching gas 26 atmosphere, and the capability of the salient part 2 as the solid immersion lens is improved.

### Preferred Embodiment 5

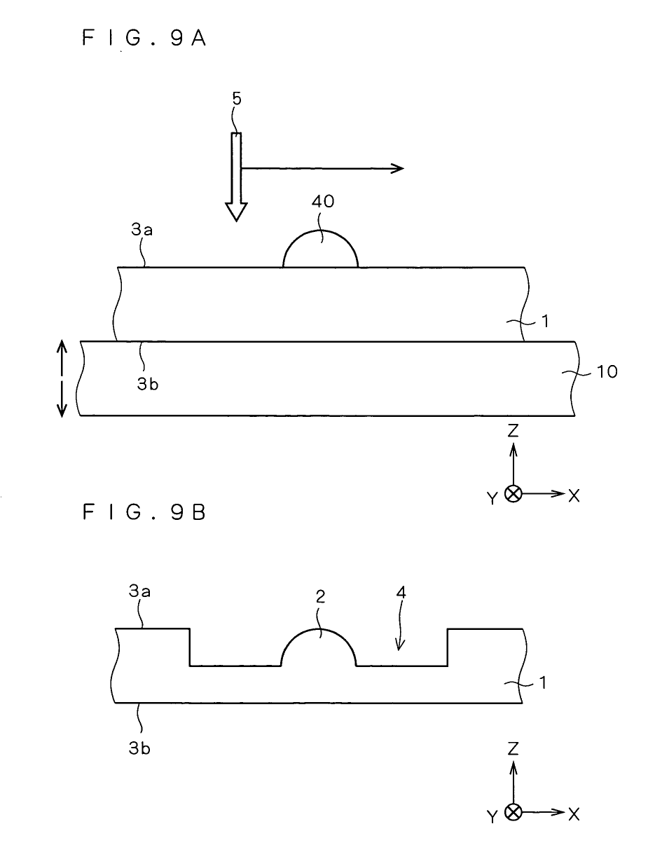

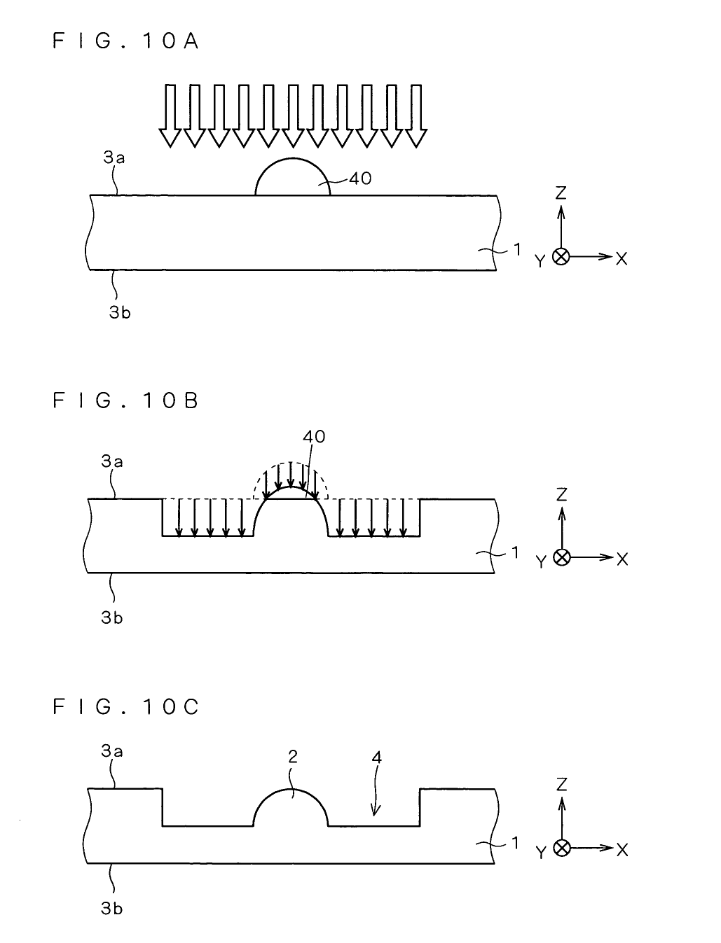

FIGS. 9A, 9B are cross-sectional views illustrating a processing method of the semiconductor substrate according to the preferred embodiment 5 of the present invention. A structure shown in FIG. 9A is a cross-sectional structure of the semiconductor substrate I before the process, and a structure shown in FIG. 9B is a cross-sectional structure of the semiconductor substrate 1 after the process. Besides, the semiconductor substrate 1 shown in FIG. 9B is formed of the same shape as that of the semiconductor substrate 1 shown in FIG. 1A. The processing method according to the present preferred embodiment 9 is described hereinafter with referring to FIGS. 9A, 9B.

First, as shown in FIG. 9A, the semiconductor substrate 1 before the process is placed on the stage 10 which can move along the Z axis direction. Moreover, a mask 40 having the same shape as the salient part 2 is placed on the main surface 3a of the semiconductor substrate 1. The salient part 2 is a hemisphere in the present preferred embodiment 5, thus the mask 40 comes to be a hemisphere.

The mask 40 can be formed by employing a mold, for example, and is formed of a material identical with that of the semiconductor substrate 1. Accordingly, in case that a silicon substrate is applied to the semiconductor substrate 1, the mask 40 is formed of silicon.

Next, the salient part 2 is formed on the main surface 3a of the semiconductor substrate 1 with irradiating the focused ion beam 5 on the mask 40 and the main surface 3a of the semiconductor substrate 1 from an upper side of the mask 40 until the mask 40 is completely removed. Concretely, the semiconductor substrate 1 and the mask 40 are processed with making the irradiation position of the focused ion beam 5 move along the X axis and the Y axis in the rectangular coordinate system Q1. The irradiation time t in each irradiation position of this time is constant, and it is expressed as t=1/a0×(dw−d0).

Moreover, at this time, the semiconductor substrate 1 is made to move in the positive direction of the Z axis with a proceeding of the processing in the negative direction of the Z axis by the stage 10 so that the focused ion beam 5 is constantly irradiated just in focus on the main surface 3a of the semiconductor substrate 1 or a surface of the mask 40 during the substrate processing, too, in the same manner as the preferred embodiment 1.

In this manner, the salient part 2 is formed with irradiating the focused ion beam 5 on the semiconductor substrate and said mask 40 until the mask 40 having the shape similar to that of the salient part 2 is removed, thus the salient part 2 having the curved surface of high precision as its surface can be formed on the main surface 3a of the semiconductor substrate 1. Accordingly, the capability of the salient part 2 as the solid immersion lens is improved and a precision of the back surface analysis is improved.

Besides, with regard to the processing method of the semiconductor substrate according to the present preferred embodiment 5, the salient part 2 can also be formed by employing a dry etching method in exchange for employing the focused ion beam. The processing method according to the present preferred embodiment 5 in this case is described hereinafter.

FIGS. 10A, 10B, 10C are cross-sectional views illustrating a method to form the salient part 2 with employing the dry etching method. A structure shown in FIG. 10A is a cross-sectional structure of the semiconductor substrate 1 before the process, a structure shown in FIG. 10B is a cross-sectional structure of the semiconductor substrate 1 in course of the process and a structure shown in FIG. 10C is a cross-sectional structure of the semiconductor substrate 1 after the process. Besides, the semiconductor substrate 1 shown in FIG. 10C has the same shape as that of the semiconductor substrate 1 shown in FIG. 1A.

First, the mask 40 is placed on the main surface 3a of the semiconductor substrate 1 as shown in FIG. 10A. Moreover, a dry etching is performed to the mask 40 and the semiconductor substrate 1 from the upper side of the mask 40 until the mask 40 is removed. A reactive ion etching employing a gas plasma is applied to the dry etching of this time, for example. According to this, the salient part 2 acting as the solid immersion lens is formed on the main surface 3a of the semiconductor substrate 1 as shown in FIG. 10C.

In this manner, the salient part 2 is formed with performing the dry etching to the semiconductor substrate 1 and said mask 40 until the mask 40 having the same shape as that of the salient part 2 is removed, thus the salient part 2 having the curved surface of high precision as its surface can be formed on the main surface 3a of the semiconductor substrate 1, and the capability of the salient part 2 as the solid immersion lens is improved.

Moreover, the salient part 2 can also be formed by irradiating the laser 25 on the mask 40 and the semiconductor substrate 1 in the etching gas 26 atmosphere in exchange for irradiating the focused ion beam 5 on them. A processing method according to the present preferred embodiment 5 in this case is described hereinafter.

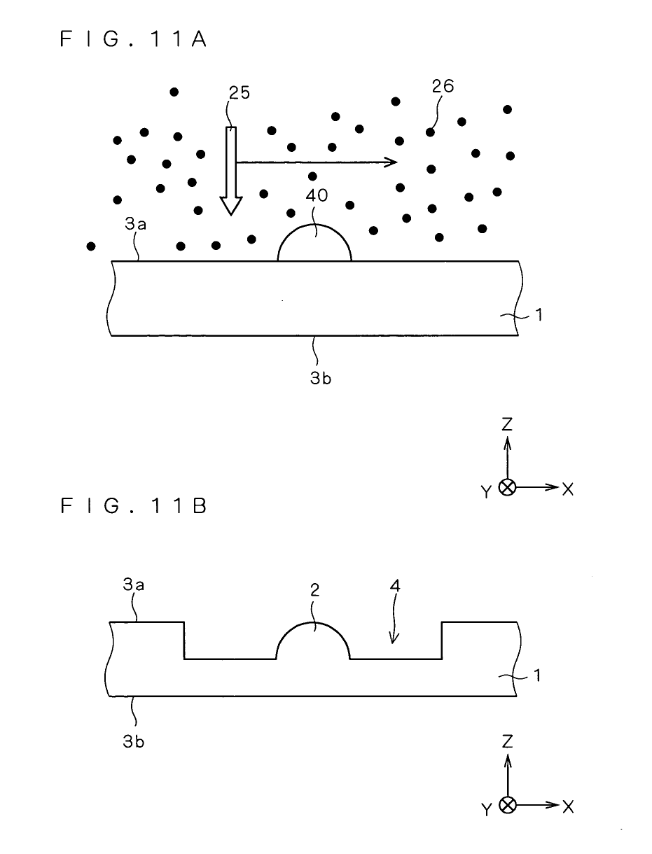

FIGS. 11A, 11B are cross-sectional views illustrating a method to form the salient part 2 by an irradiation of the laser 25 in the etching gas 26 atmosphere. A structure shown in FIG. 11A is a cross-sectional structure of the semiconductor substrate 1 before the process, and a structure shown in FIG. 11B is a cross-sectional structure of the semiconductor substrate 1 after the process. Besides, the semiconductor substrate 1 shown in FIG. 11B has the same shape as that of the semiconductor substrate 1 shown in FIG. 1A.

First, the mask 40 is placed on the main surface 3a of the semiconductor substrate 1 as shown in FIG. 11A. Moreover, the laser 25 is irradiated on the mask 40 and the semiconductor substrate 1 in the etching gas 26 atmosphere from the upper side of the mask 40 until the mask 40 is removed. Concretely, the semiconductor substrate 1 and the mask 40 are processed with making the irradiation position of the laser 25 move along the X axis and the Y axis in the rectangular coordinate system Q1. The irradiation time t in each irradiation position of this time is constant, and it is expressed as t=1/a0(dw−d0).

According to this, the salient part 2 acting as the solid immersion lens is formed on the main surface 3a of the semiconductor substrate 1 as shown in FIG. 11B.

In this manner, the salient part 2 is formed with irradiating the laser 25 on the semiconductor substrate 1 and said mask 40 in the etching gas 26 atmosphere until the mask 40 having the same shape as that of the salient part 2 is removed, thus the salient part 2 having the curved surface of high precision as its surface can be formed on the main surface 3a of the semiconductor substrate 1, and the capability of the salient part 2 as the solid immersion lens is improved.

Besides, in the present preferred embodiment 5, a case of forming the salient part 2 acting as the spherical lens is described, however, the invention according to the present preferred embodiment 5 can also be applied to a case of forming the salient part 2 acting as the non-spherical lens. The salient part 2 acting as the non-spherical lens can be formed on the main surface 3a of the semiconductor substrate 1 as shown in FIGS. 4A, 4B by placing said mask 40 which is a semiellipsoid on the semiconductor substrate 1 and irradiating the focused ion beam 5 on the semiconductor substrate 1 and the mask 40, performing the dry etching to the semiconductor substrate 1 and the mask 40 or irradiating the laser 25 on the semiconductor substrate 1 and the mask 40 in the etching gas 26 atmosphere, until the mask 40 is removed.

Moreover, the mask 40 is formed of the material identical with that of the semiconductor substrate 1 in the present preferred embodiment 5, however, in case of processing the semiconductor substrate 1 with employing the focused ion beam 5, the mask 40 can also be formed with employing other material if the material is substantially identical with that of the semiconductor substrate 1 in the cutting amount per unit of time by the focused ion beam 5. Moreover, in case of processing the semiconductor substrate 1 with employing the dry etching method, the mask 40 can also be formed with employing other material if the material has an etching rate substantially identical with that of the semiconductor substrate l. Moreover, in case of processing the semiconductor substrate 1 by the irradiation of the laser 25 in the etching gas 26 atmosphere, the mask 40 can also be formed with employing other material if the material is substantially identical with that of the semiconductor substrate 1 in the cutting amount per unit of time by the laser 25 in the etching gas 26 atmosphere.

While the invention has been shown and described in detail, the foregoing description is in all aspects illustrative and not restrictive. It is therefore understood that numerous modifications and variations can be devised without departing from the scope of the invention.

What is claimed is:

1. A processing method of a semiconductor substrate, comprising steps of:
(a) preparing a semiconductor substrate; and
(b) processing said semiconductor substrate with irradiating a focused ion beam on a main surface of said semiconductor substrate and forming a salient part which acts as a solid immersion lens and has a curved surface on said main surface, wherein
a cutting amount of said semiconductor substrate is adjusted in said step (b) by making an irradiation time of said focused ion beam to said semiconductor substrate change corresponding to an irradiation position of said focused ion beam to said semiconductor substrate.

2. The processing method of the semiconductor substrate according to claim 1, wherein
a surface of said salient part has a curved surface of rotation with a thickness direction of said semiconductor substrate as an axis of rotation, and
in said step (b), said focused ion beam is irradiated on said main surface of said semiconductor substrate with making said semiconductor substrate rotate with a thickness direction of said semiconductor substrate as an axis of rotation.

3. A processing method of a semiconductor substrate, comprising steps of:
(a) preparing a semiconductor substrate; and
(b) processing said semiconductor substrate with irradiating a laser on a main surface of said semiconductor substrate in an etching gas atmosphere and forming a salient part which acts as a solid immersion lens and has a curved surface on said main surface, wherein
a cutting amount of said semiconductor substrate is adjusted in said step (b) by making an irradiation time of said laser to said semiconductor substrate change corresponding to an irradiation position of said laser to said semiconductor substrate.

4. The processing method of the semiconductor substrate according to claim 3, wherein
a surface of said salient part has a curved surface of rotation with a thickness direction of said semiconductor substrate as an axis of rotation, and
in said step (b), said laser is irradiated on said main surface of said semiconductor substrate with making said semiconductor substrate rotate with a thickness direction of said semiconductor substrate as an axis of rotation.

5. A processing method of a semiconductor substrate, comprising steps of:
(a) preparing a semiconductor substrate; and
(b) processing said semiconductor substrate and forming a salient part which acts as a solid immersion lens and has a curved surface on a main surface of said semiconductor substrate, wherein
said step (b) includes steps of:
(b-1) placing a mask on said main surface of said semiconductor substrate, said mask being composed of a material of which a cutting amount per unit of time by a focused ion beam is substantially identical with that of said semiconductor substrate and having shape similar to that of said salient part; and
(b-2) irradiating said focused ion beam on said mask and said semiconductor substrate from an upper side of said mask until said mask is removed and forming said salient part on said main surface.
